(19) United States
(12) Patent Application Publication
(10) Pub. No.: US 2024/0112978 A1
(43) Pub. Date: Apr. 4, 2024

(54) ELECTRONIC PACKAGE

(71) Applicant: Advanced Semiconductor Engineering, Inc., Kaohsiung (TW)

(72) Inventors: Vikas GUPTA, Dallas, TX (US); Mark GERBER, Allen, TX (US)

(73) Assignee: Advanced Semiconductor Engineering, Inc., Kaohsiung (TW)

(21) Appl. No.: 17/956,682

(22) Filed: Sep. 29, 2022

(51) Int. Cl. H01L 23/373; H01L 23/00; H01L 23/31; H01L 23/538

(52) U.S. Cl. CPC H01L 23/3735; H01L 23/3121; H01L 23/5383; H01L 23/5384; H01L 23/562; H01L 24/32; H01L 2224/32225

(57) ABSTRACT

An electronic package is provided. The electronic package includes an insulating carrier, a first conductive layer, and an electronic component. The first conductive layer is disposed over the insulating carrier. The electronic component is disposed over the first conductive layer and electrically connected to the first conductive layer, wherein the insulating carrier is configured to dissipate heat from the electronic component to a second side of the insulating carrier opposite to a first side facing the electronic component.

### BACKGROUND

### 1. Technical Field

The present disclosure relates generally to an electronic package.

### 2. Description of the Related Art

With the rise in popularity of electric vehicles, power management chips are the subject of much research. Embedded chip packaging is important in terms of integration of chips. As next-generation chips are developed, increased specifications for electrical isolation and heat dissipation are required.

### SUMMARY

In one or more embodiments, an electronic package includes an insulating carrier, a first conductive layer, and an electronic component. The first conductive layer is disposed over the insulating carrier. The electronic component is disposed over the first conductive layer and electrically connected to the first conductive layer, wherein the insulating carrier is configured to dissipate heat from the electronic component to a second side of the insulating carrier opposite to a first side facing the electronic component.

In one or more embodiments, an electronic package includes a ceramic layer, a cladding layer, an electronic component, and an encapsulant. The cladding layer is over the ceramic carrier, wherein a lateral surface of the ceramic layer is exposed by the cladding layer. The electronic component is attached to the cladding layer. The encapsulant encapsulates the electronic component and covers the lateral surface of the ceramic layer.

In one or more embodiments, an electronic package includes a heat dissipation core, a stress buffer structure, an electronic component, and a dielectric structure. The heat dissipation core has a first surface and a second surface opposite to the first surface. The stress buffer structure is adjacent to at least one of the first surface and the second surface of the heat dissipation core. The electronic component is disposed over the stress buffer structure. The dielectric structure encapsulates the stress buffer structure and the electronic component.

### BRIEF DESCRIPTION OF THE DRAWINGS

Aspects of the present disclosure are best understood from the following detailed description when read with the accompanying drawings. It is noted that various features may not be drawn to scale, and the dimensions of the various features may be arbitrarily increased or reduced for clarity of discussion.

FIG. 1 is a cross-section of an electronic package in accordance with some embodiments of the present disclosure;

FIG. 2 is a cross-section of an electronic package in accordance with some embodiments of the present disclosure;

FIG. 3A is a cross-section of an electronic package in accordance with some embodiments of the present disclosure;

FIG. 3B is a top view of an electronic package in accordance with some embodiments of the present disclosure;

FIG. 4A is a cross-section of an electronic package in accordance with some embodiments of the present disclosure;

FIG. 4B is a cross-section of an electronic package in accordance with some embodiments of the present disclosure;

FIG. 5A is a cross-section of an electronic package in accordance with some embodiments of the present disclosure;

FIG. 5B is a top view of an electronic package in accordance with some embodiments of the present disclosure;

FIG. 5C is a cross-section of an electronic package in accordance with some embodiments of the present disclosure;

FIG. 6A is a cross-section of an electronic package in accordance with some embodiments of the present disclosure;

FIG. 6B is a top view of an electronic package in accordance with some embodiments of the present disclosure;

FIG. 7A is a cross-section of an electronic package in accordance with some embodiments of the present disclosure;

FIG. 7B is a top view of an electronic package in accordance with some embodiments of the present disclosure;

FIG. 8A, FIG. 8B, FIG. 8C, FIG. 8D, FIG. 8E, FIG. 8F, FIG. 8G, and FIG. 8H illustrate various operations in a method of manufacturing an electronic package in accordance with some embodiments of the present disclosure;

FIG. 9A and FIG. 9B illustrate various operations in a method of manufacturing an electronic package in accordance with some embodiments of the present disclosure;

FIG. 10A and FIG. 10B illustrate various operations in a method of manufacturing an electronic package in accordance with some embodiments of the present disclosure; and

FIG. 11A, FIG. 11B, FIG. 11C, FIG. 11D, FIG. 11E, FIG. 11F, FIG. 11G, and FIG. 11H illustrate various operations in a method of manufacturing an electronic package in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

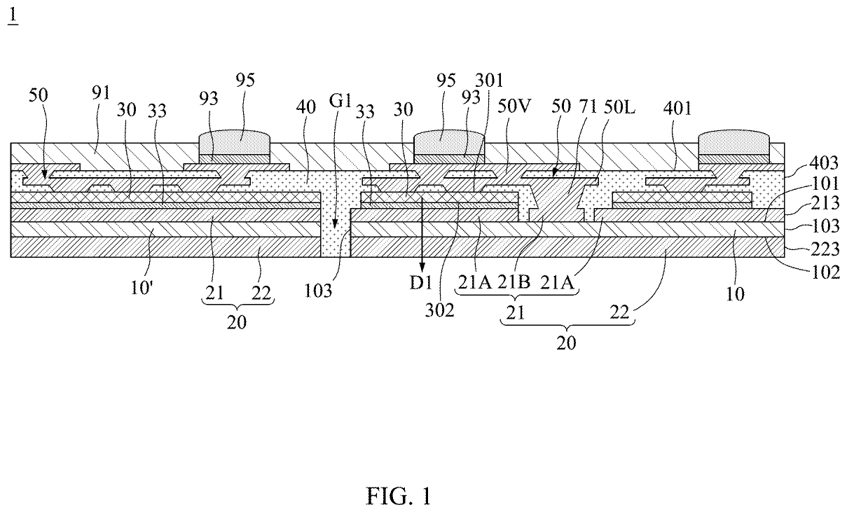

FIG. 1 is a cross-section of an electronic package 1 in accordance with some embodiments of the present disclosure. The electronic package 1 includes one or more insulating carriers 10 and 10′, one or more cladding layers 20, one or more electronic components 30, one or more adhesive layers 33, a dielectric structure 40, one or more circuit layers 50, at least one conductive via 71, an insulating layer 91, one or more conductive pads 93, and one or more electrical contacts 95.

The insulating carrier 10 may have a surface 101 (also referred to as “a top surface”), a surface 102 (also referred to as “a bottom surface”) opposite to the surface 101, and lateral surfaces 103 (also referred to as “side surfaces”) extending between the surface 101 and the surface 102. In some embodiments, the insulating carrier 10 may be configured as a heat dissipation structure (or a heat dissipation core of a carrier structure). In some embodiments, the insulating carrier 10 may be or include an inorganic layer or carrier. In some embodiments, the insulating carrier 10 may be or include a ceramic layer (e.g., Si₃N₄). In some embodiments, the ceramic layer has a dielectric strength of greater than or exceeding about 20 kV/mm. In some embodiments, the insulating carrier 10 is free of a metal layer or a metal structure. In some embodiments, the insulating carrier 10 is a homogeneous ceramic layer. In some embodiments, the insulating carrier 10 is a ceramic layer having a thickness of about 0.38 mm which may support a voltage isolation of about 6 kV or higher. In some embodiments, the insulating carrier 10 is a ceramic layer having a thickness of about 0.63 mm which may support a voltage isolation of about 13 kV or higher.

In some embodiments, the insulating carrier 10′ has a structure and/or material that may be the same as or similar to those of the insulating carrier 10, and the description thereof is omitted hereinafter. In some embodiments, the insulating carrier 10 and the insulating carrier 10′ are separated by a gap G1. In some embodiments, lateral surfaces 103 of the insulating carriers 10 and 10′ are exposed to the gap G1. In some embodiments, the combination of the insulating carrier 10 and the insulating carrier 10′ may be referred to as an integrated heat dissipation core including portions (i.e., the insulating carriers 10 and 10′) that are separated from each other by a space (e.g., the gap G1). In some embodiments, the dielectric structure 40 is further filled in the space (e.g., the gap G1) separating the portions (i.e., the insulating carriers 10 and 10′).

The cladding layer 20 may be disposed over the insulating carrier 10. In some embodiments, the cladding layer 20 is disposed on the surfaces 101 and 102 of the insulating carrier 10. In some embodiments, the cladding layer 20 directly contacts the surfaces 101 and 102 of the insulating carrier 10. In some embodiments, the lateral surface 103 of the insulating carrier 10 is exposed by the cladding layer 20. In some embodiments, a hardness of the cladding layer 20 is less than a hardness of the insulating carrier 10. In some embodiments, a stiffness of the cladding layer 20 is less than a stiffness of the insulating carrier 10. For example, a modulus of the cladding layer 20 may be less than a modulus of the insulating carrier 10. In some embodiments, the cladding layer 20 is configured as a stress buffer structure for the insulating carrier 10. In some embodiments, the cladding layer 20 is configured as a stress buffer structure for the composite structure including the insulating carrier 10 and the cladding layer 20. In some embodiments, the cladding layer 20 includes a metal layer (e.g., a copper layer), a glass-reinforced epoxy layer (e.g., an FR4 layer), a liquid crystal polymer (LCP) layer, other suitable material layers, or a combination thereof.

In some embodiments, the cladding layer 20 includes a portion 21 (also referred to as “a conductive portion,” “a conductive pattern,” or “a conductive layer”) and a portion 22 (also referred to as “a conductive portion,” “a conductive pattern,” “a conductive layer,” or “a bottom conductive pattern”) separated from the portion 21. In some embodiments, the portions 21 and 22 may be referred to as separate cladding or conductive layers (also referred to as “a first cladding layer” and “a second cladding layer” or “a first conductive layer” and “a second conductive layer”) which form the combined cladding layer 20. In some embodiments, the portion 21 is configured to support the electronic component 30. In some embodiments, the portion 21 is on the surface 101 of the insulating carrier 10, and the portion 22 is on the surface 102 of the insulating carrier 10. In some embodiments, the portion 21 is configured to support and electrically connect to the electronic component 30. In some embodiments, the portion 21 (or the conductive pattern) includes a part 21A (also referred to as “a first part”) attached to the electronic component 30 and a part 21B (also referred to as “a second part”) separated from the part 21A. In some embodiments, the insulating carrier 10 (or the heat dissipation core) is configured to dissipate heat from the electronic component 30 on a first side (e.g., the surface 101) towards a second side (e.g., the surface 102) of the insulating carrier 30 opposite to the first side. In some embodiments, the insulating carrier 10 (or the heat dissipation core) thermally connects to the portion 21 and the portion 22 of the cladding layer 20. In some embodiments, the heat is dissipated from the electronic component 30 by the insulating carrier 10 (or the heat dissipation core) along a direction D1. In some embodiments, the insulating carrier 10 is electrically insulated from the portion 21 and the portion 22 of the cladding layer 20. In some embodiments, the lateral surface 103 of the insulating carrier 10 substantially aligns with a lateral surface 213 of the portion 21 of the cladding layer 20. In some embodiments, the lateral surface 103 of the insulating carrier 10 substantially aligns with a lateral surface 223 of the portion 22 of the cladding layer 20. In some embodiments, patterns of thicknesses of the portion 21 and the portion 22 of the cladding layer 20 are symmetrically arranged with respect to the insulating carrier 10.

The electronic component 30 may be disposed over the cladding layer 20. In some embodiments, the insulating carrier 10 (or the heat dissipation core) is configured to dissipate heat from the electronic component 30. In some embodiments, the electronic component 30 is attached to the cladding layer 20. In some embodiments, the electronic component 30 is disposed over and electrically connected to the cladding layer 20 (or the metal layer). In some embodiments, the electronic component 30 is disposed over and electrically connected to the portion 21 of the cladding layer 20 (or the metal layer). In some embodiments, the portion 21 (or the conductive pattern) includes a part 21A (also referred to as “a first part”) attached to the electronic component 30 and a part 21B (also referred to as “a second part”) electrically connected to the electronic component 30 through a conductive structure. In some embodiments, the electronic component 30 has a surface 301 (also referred to as “an active surface”) and a surface 302 (also referred to as “a backside surface” or “a passive surface”).

The adhesive layer 33 may attach the electronic component 30 to the cladding layer 20. In some embodiments, the adhesive layer 33 is a conductive adhesive layer which may be, for example, a conductive gel or epoxy film (e.g., epoxy mixed with a conductive material), or other conductive material. In some embodiments, the part 21A of the portion 21 of the cladding layer 20 is electrically connected to the electronic component 30 through the adhesive layer 33. In some embodiments, the electronic component 30 is a power management chip. In some embodiments, the electronic component 30 may include conductive terminals (not shown) at the surface 302 (or the backside surface) that are electrically connected to the adhesive layer 33. In some embodiments, power may be supplied from the part 21A of the portion 21 of the cladding 20 directly through the adhesive layer 33 to the conductive terminals at the surface 302 of the electronic component 30.

The dielectric structure 40 may encapsulate the cladding layer 20 and the electronic component 30. In some embodiments, the dielectric structure 40 may be configured as a protective layer protecting the insulating carrier 10, the cladding layer 20, and the electronic component 30 from damages. In some embodiments, the dielectric structure 40 may be or include one or more dielectric layers, one or more dielectric laminates, an encapsulant, or the like. In some embodiments, the dielectric structure 40 may be or include polypropylene resin, one or more molding compounds, pre-impregnated composite fibers (e.g., pre-preg), or a combination thereof. Examples of a pre-preg may include a multilayer structure formed by stacking or laminating a number of pre-impregnated materials/sheets. In some embodiments, the dielectric structure 40 may include a plurality of dielectric layers arranged in a stacked structure, and the number of the dielectric layers can be adjusted or changed depending on different design specifications. In some embodiments, the dielectric structure 40 may include a photosensitive material, such as polyimide (PI).

In some embodiments, a lateral surface 403 of the dielectric structure 40 substantially aligns with the lateral surface 103 of the insulating carrier 10. In some embodiments, the lateral surface 103 of the insulating carrier 10 is exposed by the dielectric structure 40. In some embodiments, the lateral surface 403 of the dielectric structure 40 substantially aligns with the lateral surface 213 of the portion 21 of the cladding layer 20. In some embodiments, the composite carrier structure including the insulating carrier 10 and the cladding layer 20 is embedded in the dielectric structure 40. In some embodiments, the lateral surface 403 of the dielectric structure 40 substantially aligns with the lateral surface 223 of the portion 22 of the cladding layer 20.

The circuit layer 50 may be disposed over and electrically connected to the electronic component 30. In some embodiments, the circuit layer 50 includes one or more conductive vias 50V electrically connected to the electronic component 30. In some embodiments, the circuit layer 50 further includes one or more conductive layers 50L electrically connected to the conductive vias 50V. In some embodiments, the circuit layer 50 includes an interconnection structure including the one or more conductive vias 50V and the one or more conductive layers 50L. In some embodiments, the one or more conductive vias 50V are embedded in the dielectric structure 40. In some embodiments, a topmost conductive layer 50L is disposed on a top surface 401 of the dielectric structure 40. In some embodiments, the circuit layer 50 may be or include, for example, copper or other metal, or a metal alloy, or other conductive material.

The conductive via 71 may penetrate the dielectric structure 40. In some embodiments, the conductive via 71 is electrically connected to the portion 21 (or the conductive pattern) of the cladding layer 20. In some embodiments, the conductive via 71 electrically connects the circuit layer 50 to the part 21B of the portion 21 (or the conductive pattern) of the cladding layer 20. In some embodiments, the part 21B of the portion 21 (or the conductive pattern) of the cladding layer 20 is electrically connected to the electronic component 30 through a conductive structure (e.g., the circuit layer 50 and the conductive via 71). In some embodiments, bottom surfaces of the conductive via 51V and the conductive via 71 are at different elevations with respect to the surface 101 of the insulating carrier 10. In some embodiments, a height (or a depth) of the conductive via 71 is greater than a height (or a depth) of the conductive via 50.

The insulating layer 91 may be disposed on the top surface 401 of the dielectric structure 40. In some embodiments, the insulating layer 91 may be or include a solder mask, polypropylene resin, or other insulating materials. In some embodiments, the topmost conductive layer 50L is covered by the insulating layer 91. In some embodiments, the insulating layer 91 defines one or more openings exposing one or more portions of the topmost conductive layer 50L of the circuit layer 50.

The conductive pads 93 may be disposed on the exposed portions of the topmost conductive layer 50L of the circuit layer 50. In some embodiments, the conductive pads 93 are electrically connected to the circuit layer 50. In some embodiments, the conductive pads 93 may be or include, for example, copper or other metal, or a metal alloy, or other conductive material. In some embodiments, the conductive pads 93 may be or include a surface finish layer, which may include a nickel/gold layer, organic solderabilty preservatives (OSP), electroless nickel-immersion gold (ENIG), electroless nickel/electroless palladium/immersion gold (ENEPIG), or a combination thereof.

In some embodiments, the electrical contacts 95 are electrically connected to the circuit layer 50 through the conductive pads 93. In some embodiments, the electrical contacts 95 may be or include solder balls.

In some cases where a leadframe is used to support and embed an electronic component in a package structure, while the leadframe is widely used and cost beneficial, the leadframe usually has relatively high thickness and relatively low dielectric strength. According to some embodiments of the present disclosure, the insulating carrier 10 and/or 10′ including or being formed of a ceramic layer is used as a carrier core layer, the insulating carrier 10 and/or 10′ has a reduced thickness which is advantageous to reduction of package size, and the ceramic layer having a relatively high dielectric strength can be used in various products requiring relatively high voltage isolation (or electrical isolation). For example, the voltages in electric vehicles (EVs) and hybrid electric vehicles (HEVs) can reach as high as about 900V to about 1200, relatively high voltage isolation between device terminals and insulated modules is required in order to prevent electrical breakdown. By using the ceramic layer as the insulating carrier 10 and/or 10′ (or the carrier core), relatively high voltage isolation can be achieved without undesirably increasing the package thickness.

In addition, according to some embodiments of the present disclosure, lateral surfaces 103 of the insulating carriers 10 and 10′ are exposed by the dielectric structure 40 and the cladding layers 20, heat transferred from the electronic component 30 can be dissipated out of the electronic package 1 through the exposed lateral surfaces 103, and thus heat dissipation can be increased.

Moreover, according to some embodiments of the present disclosure, with the cladding layer 20 formed on opposite sides (e.g., the surfaces 101 and 102) of the insulating carrier 10 and/or 10′, the cladding layer 20 can serve as a stress buffer structure to reduce or restrain warpage of the insulating carrier 10 and/or 10′.

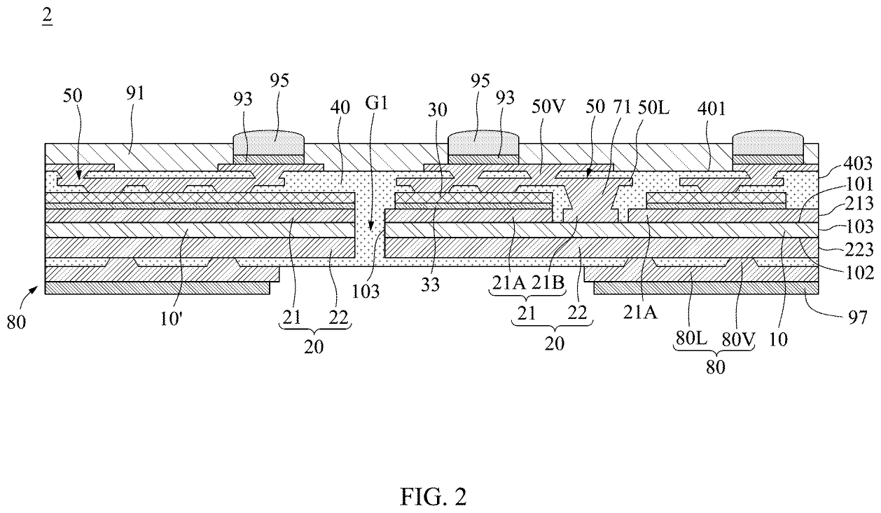

FIG. 2 is a cross-section of an electronic package 2 in accordance with some embodiments of the present disclosure. The electronic package 2 is similar to the electronic package 1 in FIG. 1, with differences therebetween as follows.

In some embodiments, the electronic package 2 further includes one or more circuit layers 80 and one or more conductive pads 97. In some embodiments, the circuit layer 50 and the circuit layer 80 are located on opposite sides of the insulating carrier 10. In some embodiments, the conductive pads 93 and the conductive pads 97 are located on opposite sides of the insulating carrier 10.

In some embodiments, the circuit layer 80 includes one or more conductive vias 80V and one or more conductive layers 80L electrically connected to the conductive vias 80V. In some embodiments, the circuit layer 80 is electrically connected to the cladding layer 20 (or the metal layer). In some embodiments, the portion 22 of the cladding layer 20 is at a side (e.g., the surface 102) of the insulating carrier 10 opposite to the electronic component 30. In some embodiments, the circuit layer 80 is electrically connected to the portion 22 of the cladding layer 20 (or the metal layer). In some embodiments, the portion 22 of the cladding layer 20 (or the metal layer) is configured to support a passive component (not shown in FIG. 2). In some embodiments, the passive component may be electrically connected to the portion 22 of the cladding layer 20 (or the metal layer) through the circuit layer 80. In some embodiments, the circuit layer 80 includes one or more materials that may be the same as or similar to that of the circuit layer 50.

In some embodiments, the conductive pads 97 are disposed on the conductive layer 80L of the circuit layer 80. In some embodiments, the conductive pads 97 are electrically connected to the circuit layer 80. In some embodiments, the conductive pads 97 include one or more materials that may be the same as or similar to that of the conductive pads 93.

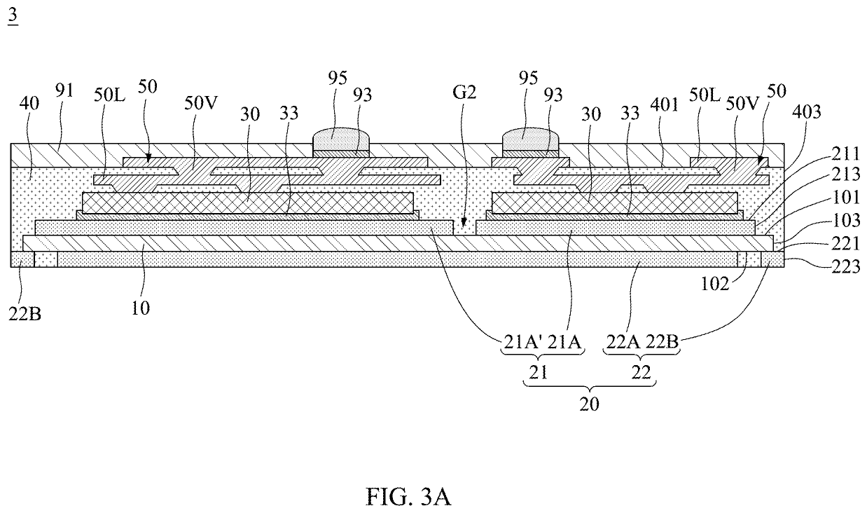

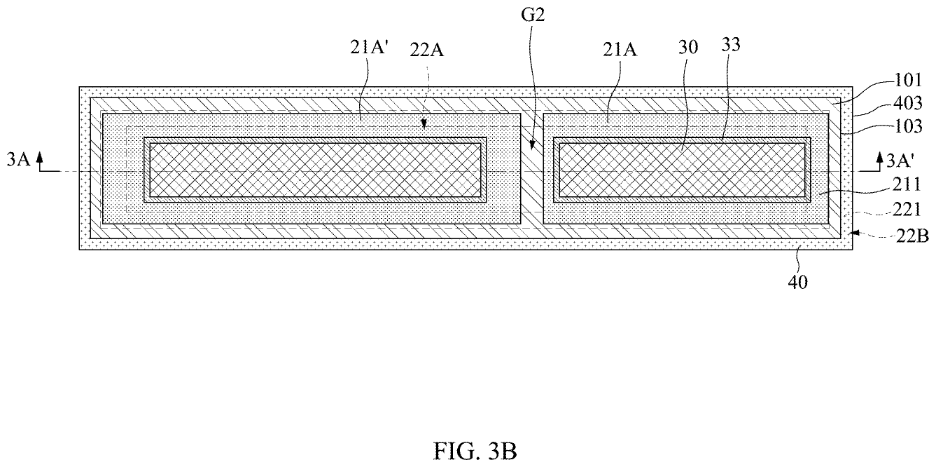

FIG. 3A is a cross-section of an electronic package 3 in accordance with some embodiments of the present disclosure, and FIG. 3B is a top view of an electronic package 3 in accordance with some embodiments of the present disclosure. In some embodiments, FIG. 3A is a cross-section along a line 3A-3A′ in FIG. 3B. Some components/elements are omitted in FIG. 3B for clarity. The electronic package 3 is similar to the electronic package 1 in FIG. 1, with differences therebetween as follows.

In some embodiments, one or more portions of the surface 101 of the insulating carrier 10 may be exposed by the portion 21 of the cladding layer 20. One or more portions of the surface 102 of the insulating carrier 10 may be exposed by the portion 22 of the cladding layer 20. In some embodiments, the lateral surface 213 of the portion 21 of the cladding layer 20 is recessed with respect to the lateral surface 103 of the insulating carrier 10. In some embodiments, the lateral surface 223 of the portion 22 of the cladding layer 20 is misaligned with the lateral surface 103 of the insulating carrier 10. In some embodiments, the lateral surface 223 of the portion 22 of the cladding layer 20 substantially aligns with the lateral surface 403 of the dielectric structure 40.

In some embodiments, the dielectric structure 40 further covers the lateral surface 103 of the insulating carrier 10. In some embodiments, the lateral surface 103 of the insulating carrier 10 directly contacts the dielectric structure 40. In some embodiments, the dielectrics structure 40 covers or contacts a portion of the surface 101 of the insulating carrier 10. In some embodiments, the dielectrics structure 40 covers or contacts a portion of the surface 102 of the insulating carrier 10. In some embodiments, the portion 22 of the cladding layer 20 includes a part 22A (also referred to as “a cladding part”) and a part 22B (also referred to as “a frame”) defining or separated by a gap which exposes a portion of the surface 102 of the insulating carrier 10. In some embodiments, the part 22B is located under a peripheral region of the insulating carrier 10.

Referring to FIG. 3B, in some embodiments, the part 22B (or the frame) surrounds the part 22A (or the cladding part). In some embodiments, a peripheral region of the surface 211 of the portion 21 of the cladding layer 20 is exposed by the electronic component 30. In some embodiments, a peripheral region of the surface 101 is exposed by the portion 21 of the cladding layer 20. In some embodiments, the portion 21 includes parts 21A and 21A′ that are separated by a gap G2 which exposes a portion of the surface 101. In some embodiments, a peripheral region of the surface 221 of the portion 20 is exposed by the insulating carrier 10.

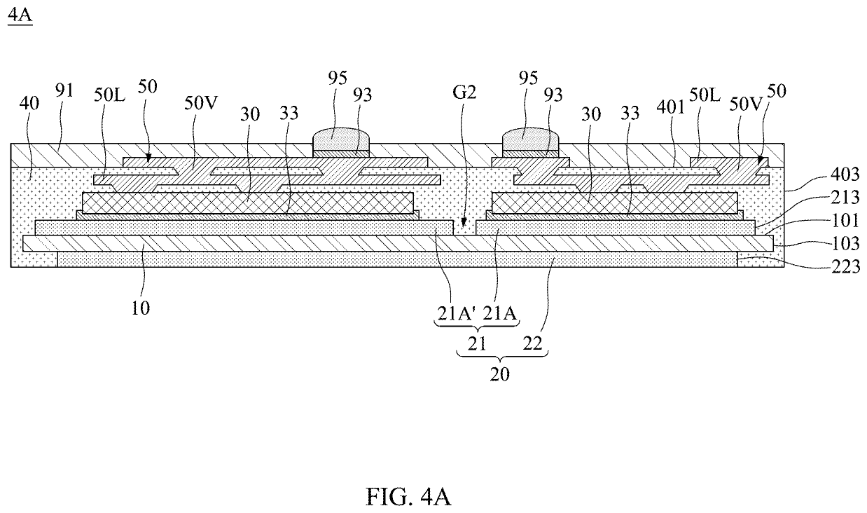

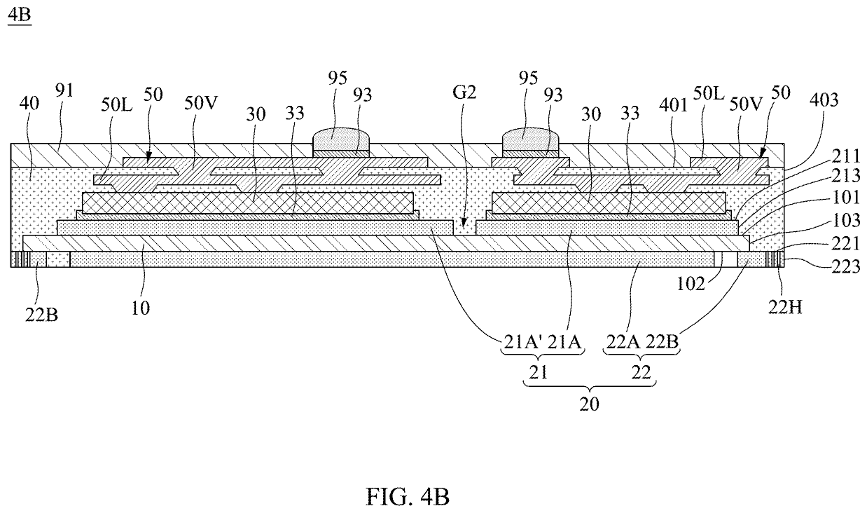

FIG. 4A is a cross-section of an electronic package 4A in accordance with some embodiments of the present disclosure. The electronic package 4A is similar to the electronic package 3 in FIGS. 3A-3B, with differences therebetween as follows.

In some embodiments, the portion 22 of the cladding layer 20 does not include a frame (e.g., the part 22B). In some embodiments, the lateral surface 213 of the portion 21 of the cladding layer 20 is recessed with respect to the lateral surface 103 of the insulating carrier 10. In some embodiments, the lateral surface 223 of the portion 22 of the cladding layer 20 is recessed with respect to the lateral surface 103 of the insulating carrier 10. In some embodiments, the dielectric structure 40 covers or encapsulates the lateral surface 223 of the portion 22 of the cladding layer 20. In some embodiments a portion of the insulating carrier 10 extends into the dielectric structure 40.

FIG. 4B is a cross-section of an electronic package 4B in accordance with some embodiments of the present disclosure. The electronic package 4B is similar to the electronic package 3 in FIGS. 3A-3B, with differences therebetween as follows.

In some embodiments, the cladding layer 20 includes a plurality of vent holes 22H. In some embodiments, the vent holes 22H are through holes that penetrate the cladding layer 20. In some embodiments, the vent holes 22H penetrate the portion 22 of the cladding layer 20. In some embodiments, the vent holes 22H penetrate the part 22B (or the frame) of the portion 22 of the cladding layer 20. In some embodiments, portions of the dielectric structure 40 are exposed to the vent holes 22H. In some embodiments, the vent holes 22H are free from overlapping the insulating carrier 10 as viewed in a direction or from perpendicular to the surface 101 of the insulating carrier 10.

According to some embodiments of the present disclosure, with the vent holes 22H formed in the cladding layer 20, air formed in the manufacturing process and trapped within the structure can pass through the vent holes 22H out of the structure. Therefore, defects which could have been formed resulted from the trapped air can be prevented, thus the yield can be increased, and the reliability of the electronic package can be increased.

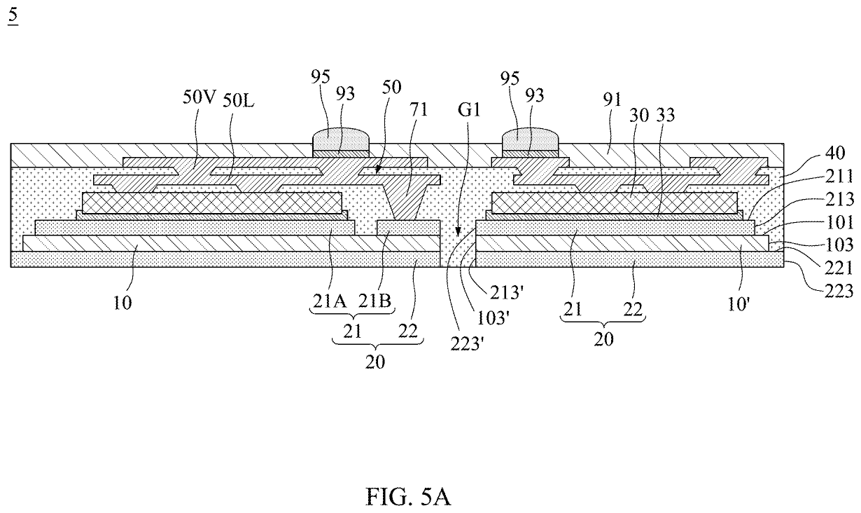

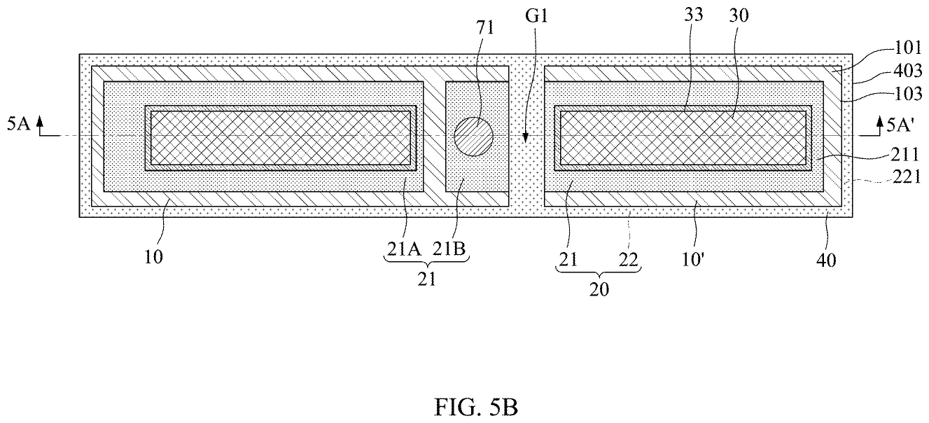

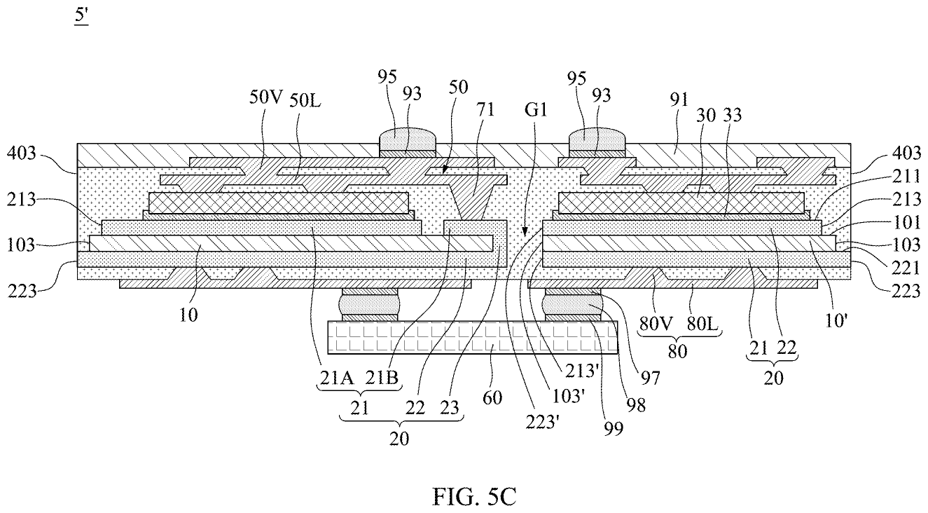

FIG. 5A is a cross-section of an electronic package 5 in accordance with some embodiments of the present disclosure, and FIG. 5B is a top view of an electronic package 5 in accordance with some embodiments of the present disclosure. In some embodiments, FIG. 5A is a cross-section along a line 5A-5A′ in FIG. 5B. Some components/elements are omitted in FIG. 5B for clarity. The electronic package 5 is similar to the electronic package 1 in FIG. 1, with differences therebetween as follows.

In some embodiments, lateral surfaces 103′ of the insulating carriers 10 and 10′, lateral surfaces 213′ of the portions 21 of the cladding layers 20, and lateral surfaces 223′ of the portions 22 of the cladding layers 20 that are exposed to the gap G1 are substantially aligned. In some embodiments, the gap G1 is filled with a portion of the dielectric structure 40. In some embodiments, the insulating carriers 10 and 10′ have lateral surfaces 103 opposite to the lateral surfaces 103′, the portions 21 of the cladding layers 20 have lateral surfaces 213 opposite to the lateral surfaces 213′, and the portions 22 of the cladding layers 20 have lateral surfaces 223 opposite to the lateral surfaces 223′. In some embodiments, the lateral surface 213 of the portion 21 of the cladding layer 20 is recessed with respect to the lateral surface 103 of the insulating carrier 10. In some embodiments, the lateral surface 103 of the insulating carrier 10 is recessed with respect to the lateral surface 223 of the portion 22 of the cladding layer 20. In some embodiments, the lateral surface 223 of the portion 22 of the cladding layer 20 substantially aligns with the lateral surface 403 of the dielectric structure 40.

FIG. 5C is a cross-section of an electronic package 5′ in accordance with some embodiments of the present disclosure. The electronic package 5′ is similar to the electronic package 5 in FIGS. 5A-5B, with differences therebetween as follows.

In some embodiments, the electronic package 5′ further includes a passive component 60, a connection structure including conductive pads 97 and 99 and a connection element 98.

In some embodiments, the passive component 60 is electrically connected to the circuit layer 80 through the conductive pads 97 and 99 and the connection element 98. In some embodiments, the conductive pads 99 include one or more materials that may be the same as or similar to those of the conductive pads 93. In some embodiments, the connection elements 98 may be or include one or more soldering materials. For example, the connection elements 98 may be or include solder balls.

In some embodiments, the electronic component 30 is disposed over the portion 21 of the cladding layer 20. In some embodiments, the cladding layer 20 further includes a portion 23 (also referred to as “a vertical conductive pattern) electrically connecting the portion 21 (or the conductive pattern) to the portion 22 (or the bottom conductive portion). In some embodiments, the portion 23 of the cladding layer 20 extends along the lateral surface 103 of the insulating carrier 10. In some embodiments, the electronic component 30 is disposed over the portion 21 of the cladding layer 20 and electrically connected to the portion 22 of the cladding layer 20. In some embodiments, the portion 23 is located at a corner region of the insulating carrier 10. In some embodiments, the portion 23 may be or include a pillar, a line, a film or layer, or a combination thereof.

In some embodiments, the portion 22 of the cladding layer 20 is configured to support the passive component 60. In some embodiments, the passive component 60 is electrically connected to the electronic component 30. In some embodiments, the passive component 60 is electrically connected to the portion 22 through the circuit layer 80, the conductive pads 97 and 99, and the connection element 98. In some embodiments, the passive component 60 is electrically connected to the circuit layer 50 through the portions 21, 22 and 23 of the cladding layer 20. The passive component 60 may be or include a capacitor, an inductor, a resistor or the like. In some other embodiments, the passive component 60 may be disposed adjacent to or side-by-side with the electronic component 30. In some other embodiments, a plurality of passive components 60 may be disposed on opposite sides (e.g., the surface 101 and the surface 102) of the insulating carrier 10.

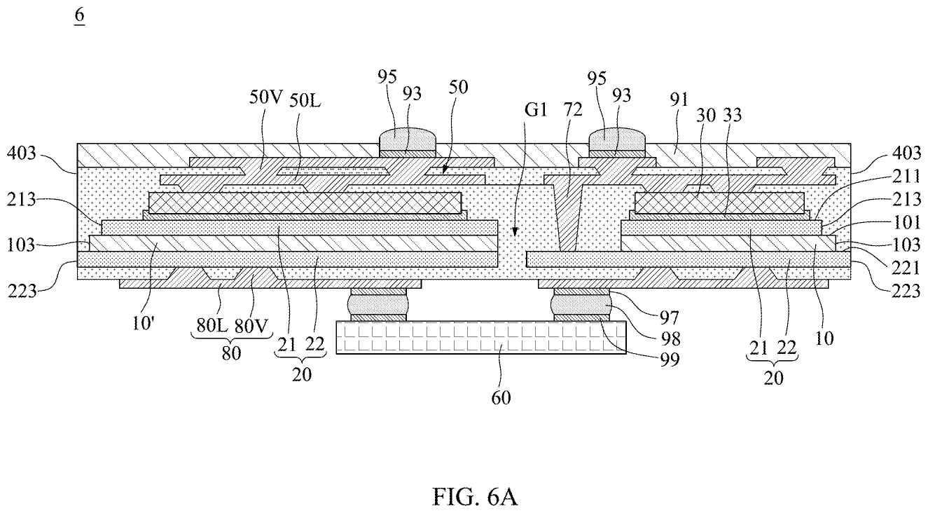

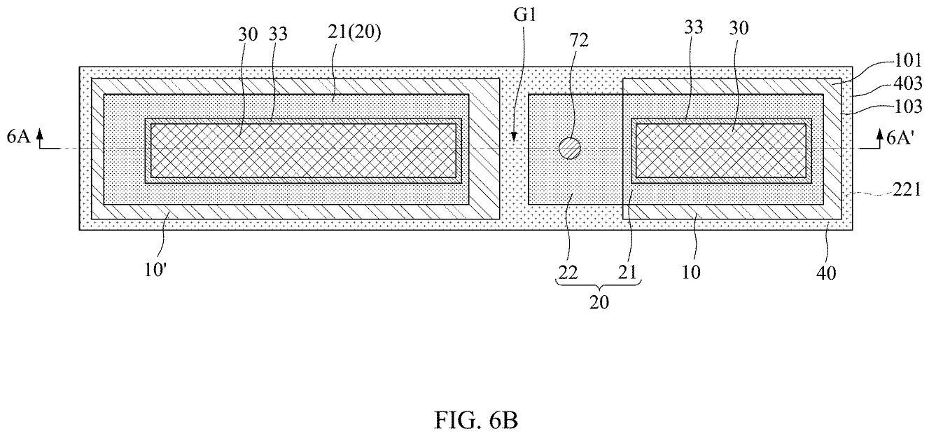

FIG. 6A is a cross-section of an electronic package 6 in accordance with some embodiments of the present disclosure, and FIG. 6B is a top view of an electronic package 6 in accordance with some embodiments of the present disclosure. In some embodiments, FIG. 6A is a cross-section along a line 6A-6A′ in FIG. 6B. Some components/elements are omitted in FIG. 6B for clarity. The electronic package 6 is similar to the electronic package 5′ in FIG. 5C, with differences therebetween as follows.

In some embodiments, the electronic package 6 includes at least one conductive via 72 penetrating the dielectric structure 40. In some embodiments, the conductive via 72 electrically connects the circuit layer 50 to the portion 22 of the cladding layer 20. In some embodiments, the conductive via 72 is spaced apart from the portion 21 of the cladding layer 20 and directly contacts the portion 22 of the cladding layer 20. In some embodiments, the conductive via 72 is between the insulating carrier 10 and the insulating carrier 10′ In some embodiments, the passive component 60 is electrically connected to the circuit layer 50 through the conductive pads 97 and 99, the connection element 98, the circuit layer 80, and the portion 22 of the cladding layer 20. In some embodiments, the combination of the insulating carrier 10 and the insulating carrier 10′ may be referred to as an integrated heat dissipation core including portions (i.e., the insulating carriers 10 and 10′) that are separated from each other by a space (e.g., the gap G1), and the dielectric structure 40 is further filled in the space (e.g., the gap G1). In some embodiments, the conductive via 72 penetrates the dielectric structure 40 in the space and electrically connected to the electronic component 30.

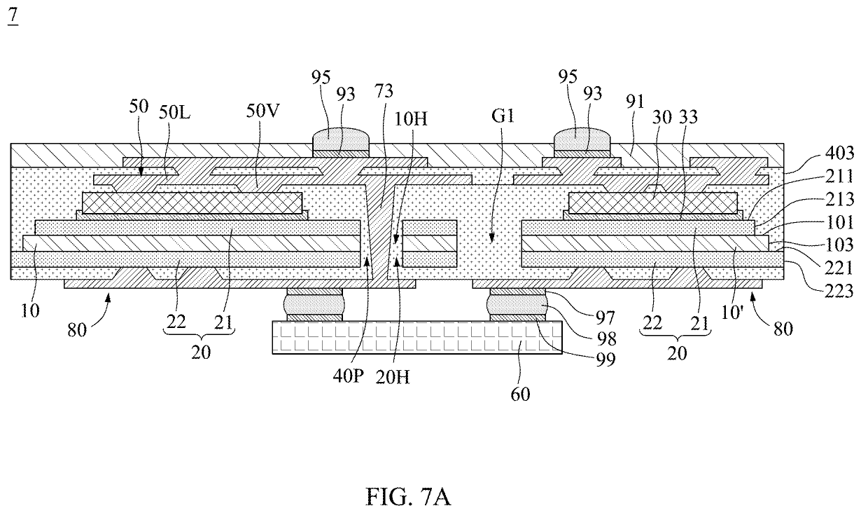

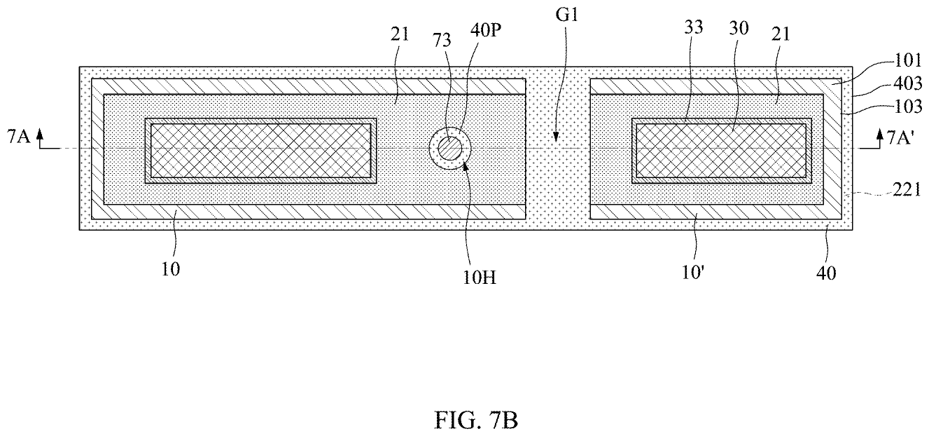

FIG. 7A is a cross-section of an electronic package 7 in accordance with some embodiments of the present disclosure, and FIG. 7B is a top view of a semiconductor package 7 structure in accordance with some embodiments of the present disclosure. In some embodiments, FIG. 7A is a cross-section along a line 7A-7A′ in FIG. 7B. Some components/elements are omitted in FIG. 7B for clarity. The electronic package 7 is similar to the electronic package 5′ in FIG. 5C, with differences therebetween as follows.

In some embodiments, the electronic package 7 includes at least one conductive via 73 penetrating the dielectric structure 40. In some embodiments, the conductive via 73 electrically connects the circuit layer 50 to the circuit layer 80. In some embodiments, the conductive via 73 directly contacts the circuit layer 80. In some embodiments, the insulating carrier 10 defines a through hole 10H, and the conductive via 73 passes through the through hole 10H to electrically connect the circuit layer 50 to the circuit layer 80. In some embodiments, the passive component 60 is electrically connected to the circuit layer 50 through the conductive pads 97 and 99, the connection element 98, the circuit layer 80, and the conductive via 73. In some embodiments, a portion 40P of the dielectric structure 40 is within the through hole 10H and electrically isolates the conductive via 73 from the cladding layer 20. In some embodiments, the cladding layer 20 defines a through hole 20H that is substantially aligned with the through hole 10H of the insulating carrier 10. In some embodiments, the combination of the insulating carrier 10 and the insulating carrier 10′ may be referred to as an integrated heat dissipation core including portions (i.e., the insulating carriers 10 and 10′) that are separated from each other by a space (e.g., the gap G1 and the through hole 10H). In some embodiments, the dielectric structure 40 is further filled in the space (e.g., the gap G1 and/or the through hole 10H) separating the portions (i.e., the insulating carriers 10 and 10′). In some embodiments, the conductive via 73 penetrates the dielectric structure 40 in the space and electrically connected to the electronic component 30.

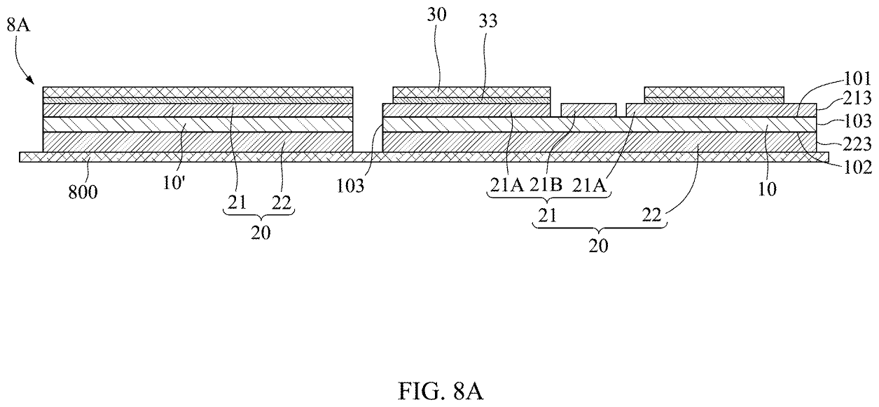

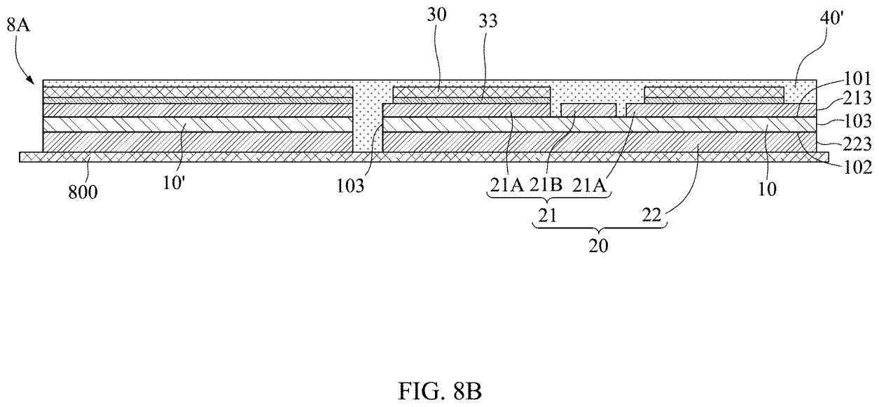

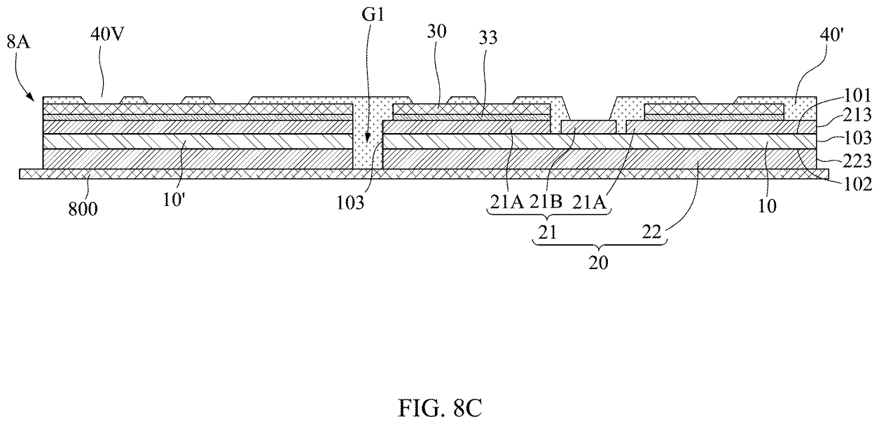

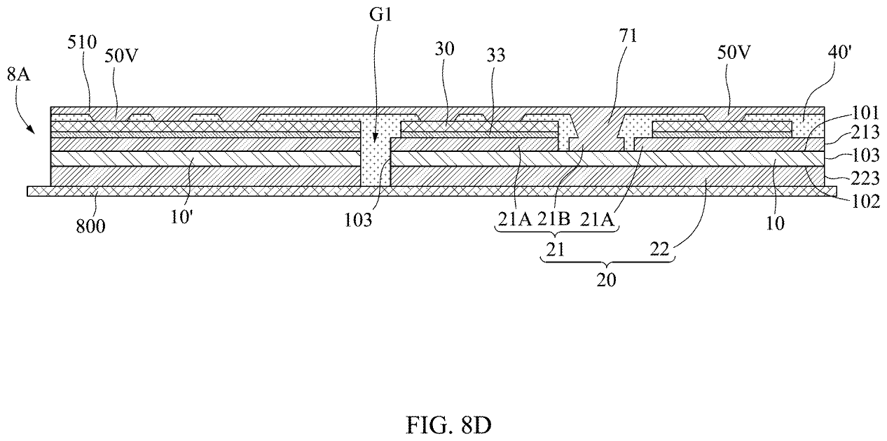

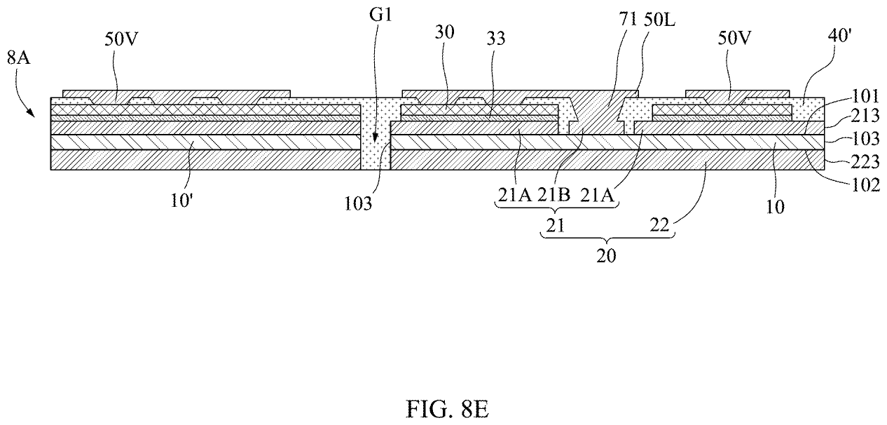

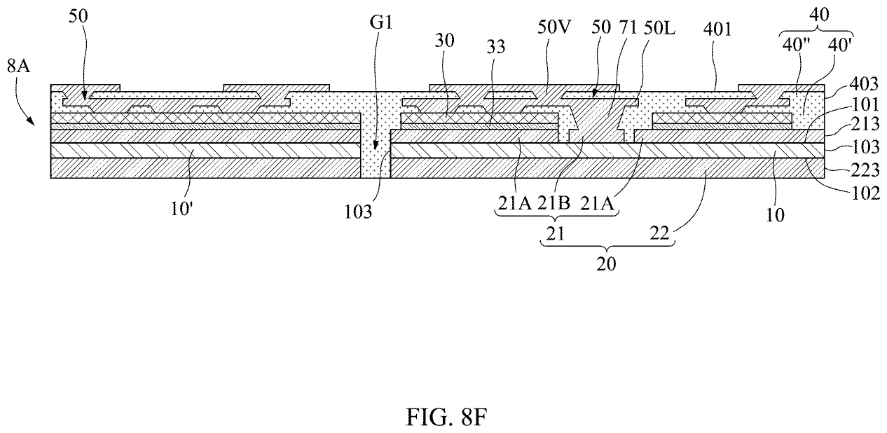

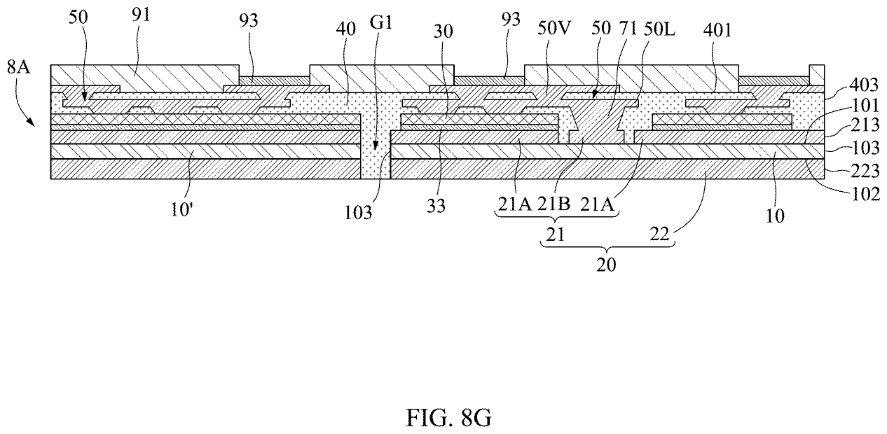

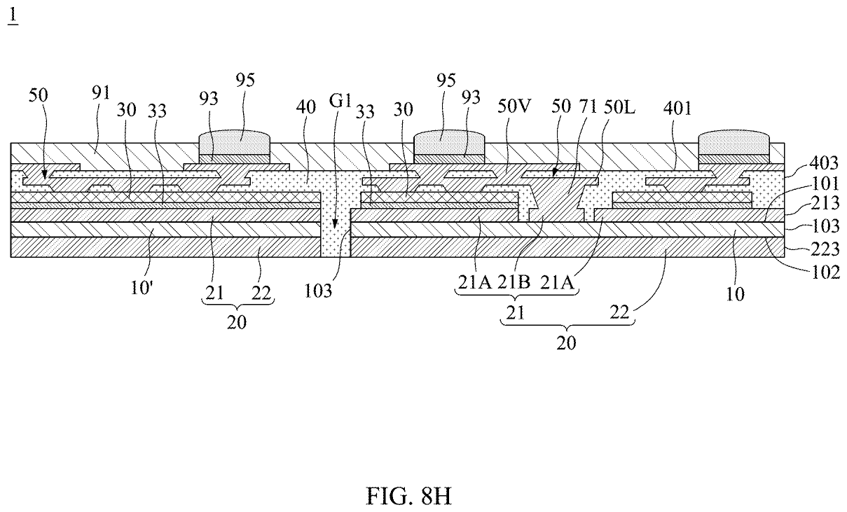

FIG. 8A, FIG. 8B, FIG. 8C, FIG. 8D, FIG. 8E, FIG. 8F, FIG. 8G, and FIG. 8H illustrate various operations in a method of manufacturing an electronic package 1 in accordance with some embodiments of the present disclosure.

Referring to FIG. 8A, a carrier structure 8A including insulating carriers 10 and 10′ and cladding layers 20 having portions 21 and 22 may be disposed on a temporary carrier 800, and electronic components 30 may be attached to the carrier structure 8A. In some embodiments, the temporary carrier 800 may be a strip or in a strip form. In some embodiments, the temporary carrier 800 may be or include a tape. In some embodiments, adhesive layers 33 may be disposed on top surfaces of the cladding layers 20 to attach the electronic components 30 to the carrier structure 8A. In some embodiments, a hardness of the cladding layer 20 is less than a hardness of the insulating carriers 10 and 10′. For example, a modulus of the cladding layer 20 may be less than a modulus of the insulating carriers 10 and 10′.

In some embodiments, the cladding layer 20 includes copper, and the insulating carriers 10 and 10′ include ceramic layers. In some embodiments, the cladding layer 20 may be bonded to the insulating carriers 10 and 10′ by a direct bond copper (DBC) process, and the DBC process may be performed at about 1000° C. to about 1100° C., e.g., about 1065° C. The DBC process may form bonds as a result of melting and diffusion between the ceramic layer and the copper layer. In some embodiments, the cladding layer 20 may be bonded to the insulating carriers 10 and 10′ by an active metal brazing (AMB) process, and the AMB process may be performed at about 750° C. to about 850° C., e.g., about 800° C. The AMB process may create a high-temperature brazed joint between copper and the ceramic material (e.g., Si₃N₄).

Referring to FIG. 8B, a dielectric layer 40′ may be formed on the carrier structure 8A and the electronic components 30 by a lamination technique.

Referring to FIG. 8C, vias 40V may be formed through the dielectric layer 40′ to expose portions of the electronic components 30. The vias 40V may be formed by laser drilling.

Referring to FIG. 8D, a conductive material 510 may be formed on the dielectric layer 40′ and in the vias 40V. In some embodiments, the conductive material 510 is electrically connected to the electronic components 30. The portions of the conductive material 510 in the vias 40V form conductive vias 50V. The conductive material 510 may be formed by coating, sputtering, plating, or other suitable technique.

Referring to FIG. 8E, a patterning operation may be performed on the conductive material 510 to form a conductive layer 50L on the dielectric layer 40′ and electrically connected to the conductive vias 50V. The patterning operation may be performed by etching. In some embodiments, the temporary carrier 800 is removed before the patterning operation.

Referring to FIG. 8F, a dielectric layer 40″ may be further formed on the dielectric layer 40′ to form a dielectric structure 40, and operations similar to those illustrated in FIGS. 8C to 8E may be performed to form an additional conductive layer 50L and conductive vias 50V over and electrically connected to the previously formed conductive layer 50L and the conductive vias 50V. The conductive layers 50L and the conductive vias 50V may form a circuit layer 50.

Referring to FIG. 8G, an insulating layer 91 may be formed on a top surface 401 of the dielectric structure 40, and conductive pads 93 may be formed in openings of the insulating layer 91 and on the circuit layer 50.

Referring to FIG. 8H, electrical contacts 95 may be disposed on the conductive pads 93. In some embodiments, a mark (not shown) may be disposed or formed on a surface of the as-formed structure (e.g., on the insulating layer 91) by, for example, using laser. In some embodiments, a singulation operation may then be performed to form a plurality of electronic packages 1 shown in FIG. 1. In some embodiments, the singulation operation may be performed by sawing or etching technique.

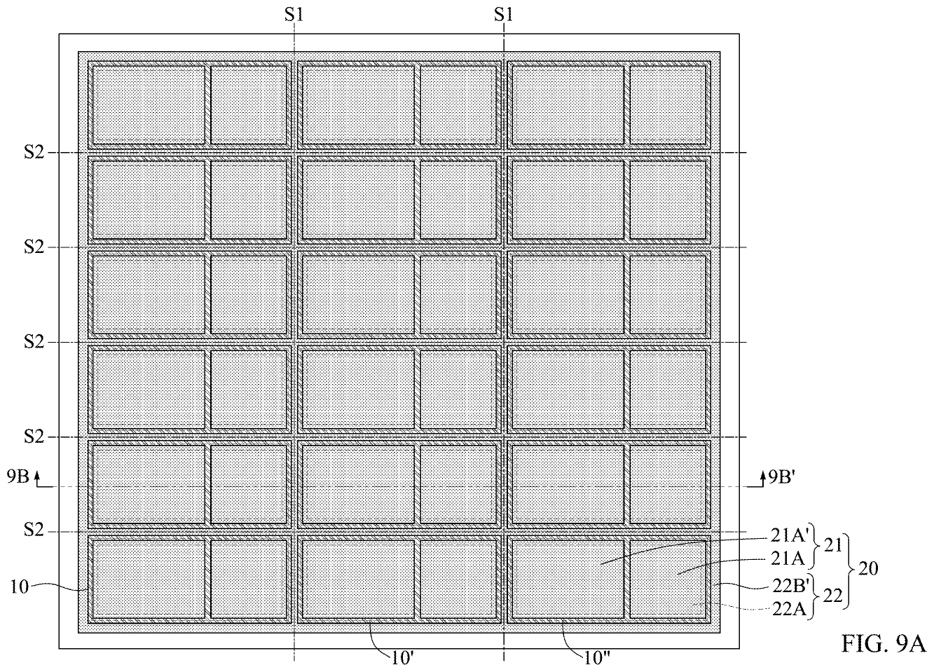

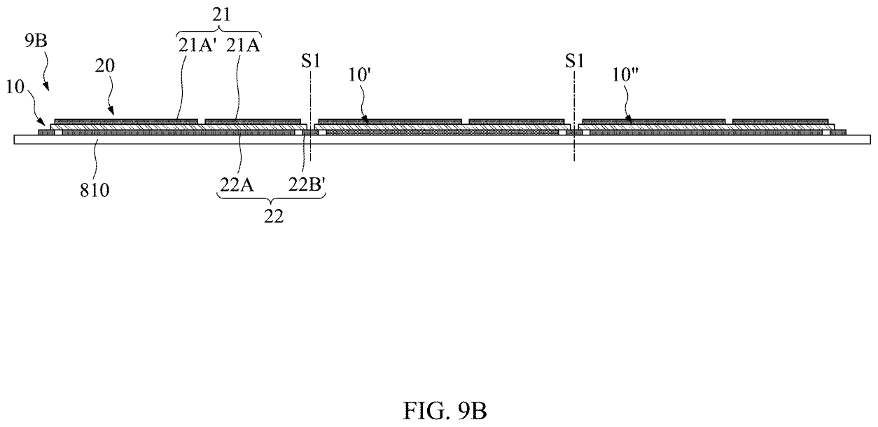

FIG. 9A and FIG. 9B illustrate various operations in a method of manufacturing an electronic package 3A in accordance with some embodiments of the present disclosure. In some embodiments, FIG. 9A shows a top view of a strip form structure, and FIG. 9B shows a cross-section along a line 9B-9B′ in FIG. 9A.

In some embodiments, a carrier structure 9B including insulating carriers 10, 10′ and 10″ and cladding layers 20 having portions 21 and 22 may be disposed on a temporary carrier 800. In some embodiments, each of the portions 21 includes parts 21A and 21A′. In some embodiments, the portion 22 includes a frame part 22B′ and a plurality of cladding parts 22A surrounded by the frame part 22B′. In some embodiments, the frame part 22B′ may be in a strip form. In some embodiments, the temporary carrier 800 may be in a strip form. In some embodiments, a hardness of the frame part 22B′ of the cladding layer 20 is less than a hardness of the insulating carriers. For example, a modulus of the frame part 22B′ of the cladding layer 20 may be less than a modulus of the insulating carriers.

Next, electronic components 30 may be attached to the parts 21A and 21A′ of the carrier structure 9B, and then operations similar to those illustrated in FIGS. 8B to 8H may be performed to form the electronic package 3A illustrated in FIGS. 3A-3B. In some embodiments, the singulation operation may be performed along scribing lines S1 and S2. In some embodiments, after the temporary carrier 800 is removed, the singulation operation is performed by sawing or cutting through the frame part 22B′ and the dielectric structure 40 along the scribing lines S1 and S2.

According to some embodiments of the present disclosure, with the frame part 22B′ being softer than the insulating carriers, in addition to the strip form frame part 22B′ increasing the structural support for the insulating carriers in the manufacturing process, the singulation operation may be performed by sawing or cutting through the frame part 22B′ without sawing or cutting through the relatively hard insulating carriers, the relatively soft frame part 22B′ can reduce damages to the sawing or cutting tool.

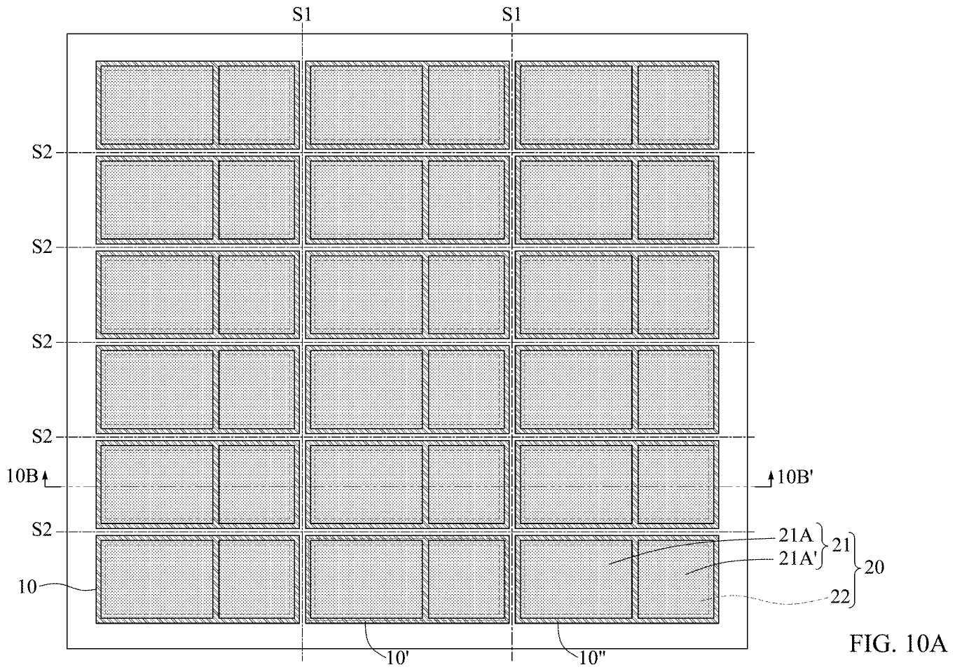

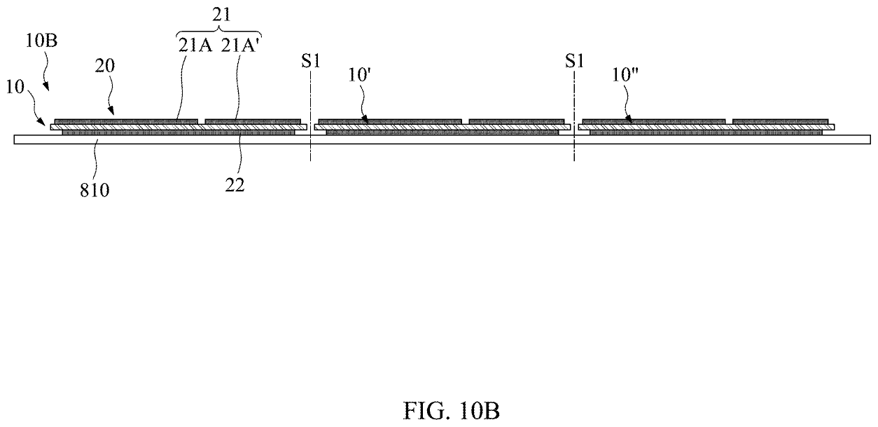

FIG. 10A and FIG. 10B illustrate various operations in a method of manufacturing an electronic package 4A in accordance with some embodiments of the present disclosure. In some embodiments, FIG. 10A shows a top view of a strip form structure, and FIG. 10B shows a cross-section along a line 10B-10B′ in FIG. 10A.

In some embodiments, a carrier structure 10B including insulating carriers 10, 10′ and 10″ and cladding layers 20 having portions 21 and 22 may be disposed on a temporary carrier 800. In some embodiments, each of the portions 21 includes parts 21A and 21A′. In some embodiments, each of the portions 22 is disposed under a corresponding insulating carrier (e.g., the insulating carriers 10, 10′, or 10″). In some embodiments, the temporary carrier 800 may be in a strip form.

Next, electronic components 30 may be attached to the parts 21A and 21A′ of the carrier structure 10B, and then operations similar to those illustrated in FIGS. 8B to 8H may be performed to form the electronic package 4A illustrated in FIG. 4A. In some embodiments, the singulation operation may be performed along scribing lines S1 and S2. In some embodiments, after the temporary carrier 800 is removed, the singulation operation is performed by sawing or cutting through the dielectric structure 40 along the scribing lines S1 and S2.

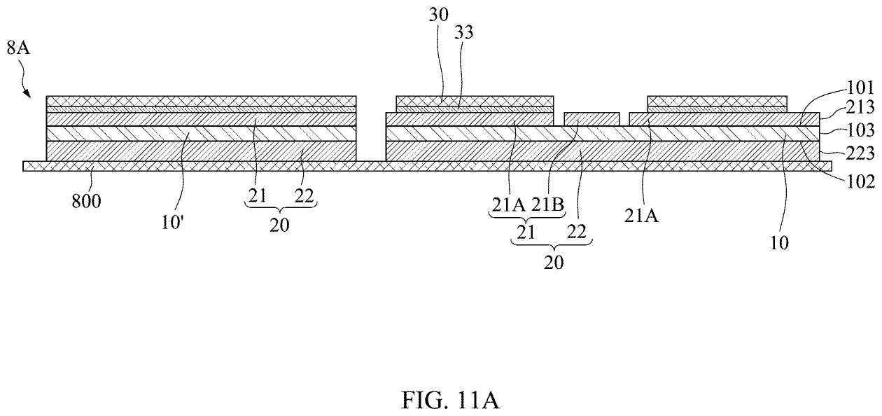

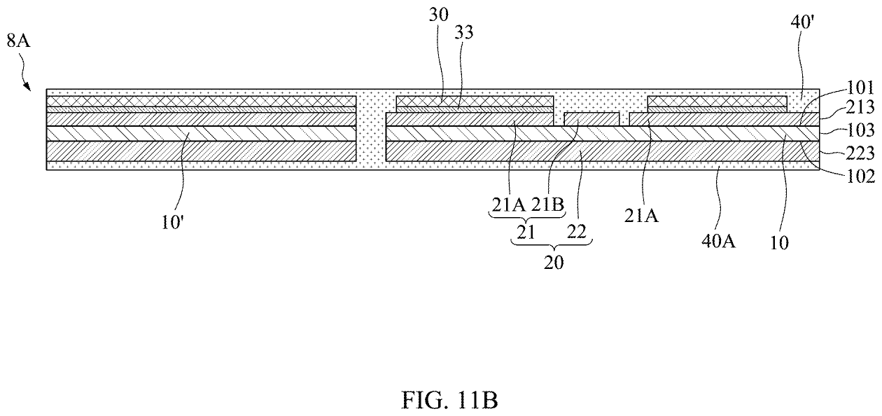

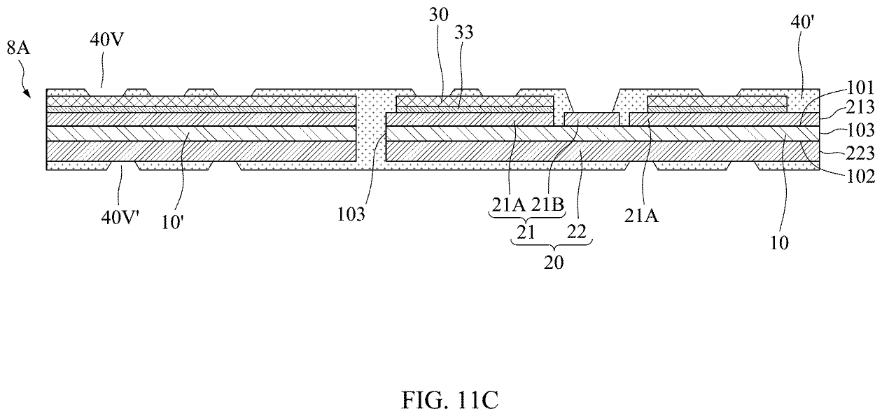

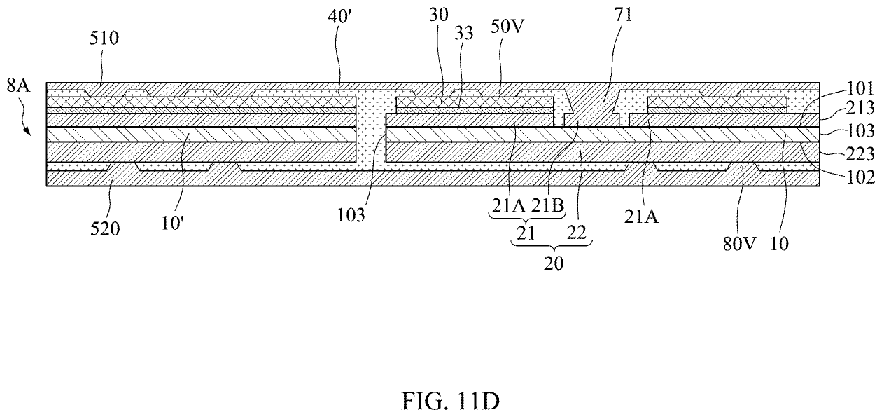

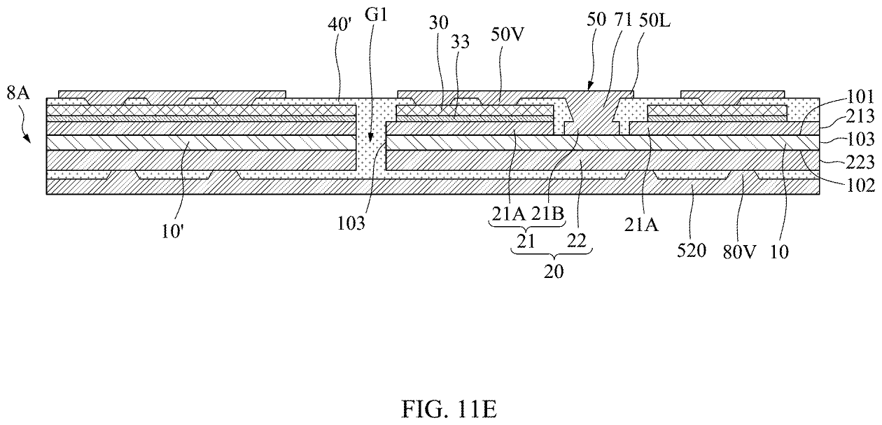

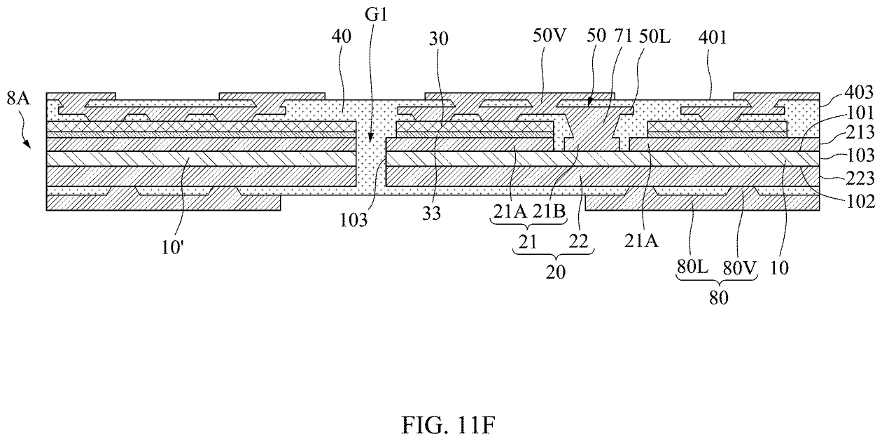

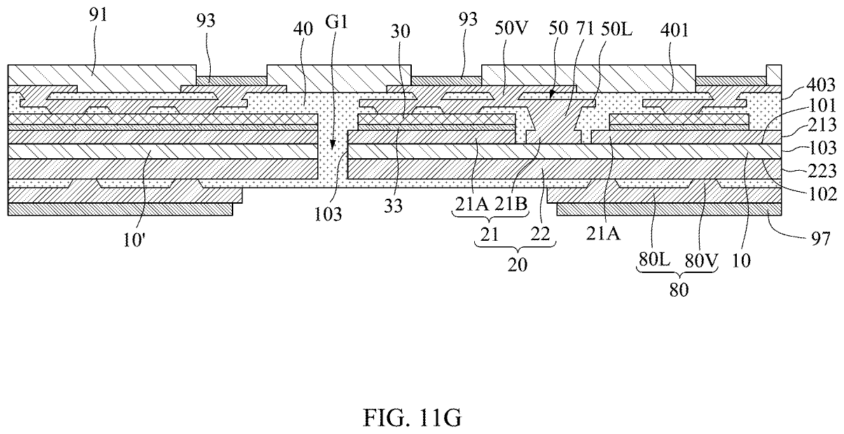

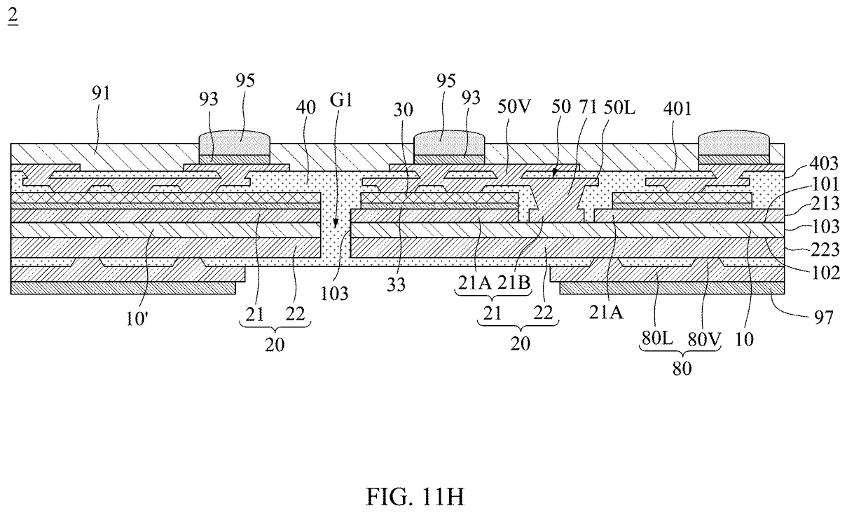

FIG. 11A, FIG. 11B, FIG. 11C, FIG. 11D, FIG. 11E, FIG. 11F, FIG. 11G, and FIG. 11H illustrate various operations in a method of manufacturing an electronic package 2 in accordance with some embodiments of the present disclosure.

Referring to FIG. 11A, a carrier structure 8A including insulating carriers 10 and 10′ and cladding layers 20 having portions 21 and 22 may be disposed on a temporary carrier 800, and electronic components 30 may be attached to the carrier structure 8A. In some embodiments, the temporary carrier 800 may be in a strip form. In some embodiments, the temporary carrier 800 may be or include a tape. In some embodiments, adhesive layers 33 may be disposed on top surfaces of the cladding layers 20 to attach the electronic components 30 to the carrier structure 8A.

Referring to FIG. 11B, a dielectric layer 40′ may be formed on the carrier structure 8A and the electronic components 30 by a lamination technique. In some embodiments, the temporary carrier 800 may be removed, and a dielectric layer 40A may be formed on portions 22 of the cladding layers 20 and the dielectric structure 40′.

Referring to FIG. 11C, vias 40V may be formed through the dielectric layer 40′ to expose portions of the electronic components 30, and vias 40V′ may be formed through the dielectric layer 40A to expose portions of the portions 22 of the cladding layer 20. The vias 40V and 40V′ may be formed by laser drilling.

Referring to FIG. 11D, a conductive material 510 may be formed on the dielectric layer 40′ and in the vias 40V, and a conductive material 520 may be formed on the dielectric layer 40A and in the vias 40V′. In some embodiments, the conductive material 510 is electrically connected to the electronic components 30, and the conductive material 520 is electrically connected to the portions 22 of the cladding layer 20. The portions of the conductive material 510 in the vias 40V form conductive vias 50V. The portions of the conductive material 520 in the vias 40V′ form conductive vias 80V. The conductive materials 510 and 520 may be formed by coating, sputtering, plating, or other suitable technique.

Referring to FIG. 11E, the conductive material 510 may be patterned to form a conductive layer 50L on the dielectric layer 40′ and electrically connected to the conductive vias 50V. The patterning operation may be performed by etching.

Referring to FIG. 11F, a dielectric layer 40″ may be further formed on the dielectric layer 40′ to form a dielectric structure 40, and operations similar to those illustrated in FIGS. 8C to 8E may be performed to form an additional conductive layer 50L and conductive vias 50V over and electrically connected to the previously formed conductive layer 50L and the conductive vias 50V. The conductive layers 50L and the conductive vias 50V may form a circuit layer 50. In some embodiments, a patterning operation similar to that illustrated in FIG. 11E may be performed on the conductive material 520 to form a conductive layer 80L on the dielectric layer 40A and electrically connected to the conductive vias 80V.

Referring to FIG. 11G, an insulating layer 91 may be formed on a top surface 401 of the dielectric structure 40, and conductive pads 93 may be formed in openings of the insulating layer 91 and on the circuit layer 50. In some embodiments, conductive pads 97 may be formed on the circuit layer 80.

Referring to FIG. 11H, electrical contacts 95 may be disposed on the conductive pads 93. In some embodiments, a singulation operation may then be performed to form a plurality of electronic packages 2 shown in FIG. 2. In some embodiments, the singulation operation may be performed by sawing or etching technique.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of said numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” or “about” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than or no greater than 0.5 μm.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations do not limit the present disclosure. It can be clearly understood by those skilled in the art that various changes may be made, and equivalent components may be substituted within the embodiments without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and the like. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. An electronic package, comprising:
an insulating carrier; and
a first conductive layer disposed over the insulating carrier; and
an electronic component disposed over the first conductive layer and electrically connected to the first conductive layer, wherein the insulating carrier is configured to dissipate heat from the electronic component to a second side of the insulating carrier opposite to a first side facing the electronic component.

2. The electronic package as claimed in claim 1, further comprising a second conductive layer separated from the first conductive layer, and the insulating carrier thermally connects to the first conductive layer and the second conductive layer.

3. The electronic package as claimed in claim 2, wherein the first conductive layer is closer to the electronic component than the second conductive layer is.

4. The electronic package as claimed in claim 3, wherein the electronic component is electrically connected to the second conductive layer.

5. The electronic package as claimed in claim 2, wherein the insulating carrier is electrically insulated from the first conductive layer and the second conductive layer.

6. The electronic package as claimed in claim 2, wherein the second conductive layer is configured to support a passive component, and the passive component is electrically connected to the electronic component.

7. The electronic package as claimed in claim 1, further comprising:
a dielectric layer encapsulating the first conductive layer and the electronic component; and
a circuit layer disposed over and electrically connected to the electronic component.

8. The electronic package as claimed in claim 7, wherein the dielectric layer further contacts a side surface of the insulating carrier.

9. An electronic package, comprising:
a ceramic layer;
a cladding layer over the ceramic carrier, wherein a lateral surface of the ceramic layer is exposed by the cladding layer;
an electronic component attached to the cladding layer; and
an encapsulant encapsulating the electronic component and covering the lateral surface of the ceramic layer.

10. The electronic package as claimed in claim 9, wherein a stiffness of the cladding layer is less than a stiffness of the ceramic layer.

11. The electronic package as claimed in claim 9, wherein the lateral surface of the ceramic layer directly contacts the encapsulant.

12. The electronic package as claimed in claim 9, further comprising a second cladding layer separated from the cladding layer, wherein the cladding layer is configured to support the electronic component, and wherein the second cladding layer is at a side of the ceramic layer opposite to the electronic component and configured to restrain a warpage

13. The electronic package as claimed in claim 12, wherein the second cladding layer has a lateral surface misaligned with the lateral surface of the ceramic layer.

14. The electronic package as claimed in claim 12, wherein patterns or thicknesses of the cladding layer and the second cladding layer are substantially symmetrically arranged with respect to the ceramic layer.

15. An electronic package, comprising:
a heat dissipation core having a first surface and a second surface opposite to the first surface;
a stress buffer structure adjacent to at least one of the first surface and the second surface of the heat dissipation core;
an electronic component disposed over the stress buffer structure; and
a dielectric structure encapsulating the stress buffer structure and the electronic component.

16. The electronic package as claimed in claim 15, further comprising:
a circuit layer over the electronic component; and
a conductive via penetrating the dielectric structure and electrically connecting the circuit layer to the stress buffer structure.

17. The electronic package as claimed in claim 16, wherein the stress buffer structure comprises a first conductive layer on the first surface of the heat dissipation core and a second conductive layer on the second surface of the heat dissipation core, and the conductive via is electrically connected to the first conductive layer or the second conductive layer.

18. The electronic package as claimed in claim 15, wherein in a cross-sectional view, the heat dissipation core comprises a first portion and a second portion separated from the first portion, and the dielectric structure is further filled in a space separating the first portion and the second portion of the heat dissipation core.

19. The electronic package as claimed in claim 18, further comprising a conductive via penetrating the dielectric structure in the space and electrically connected to the electronic component.

20. The electronic package as claimed in claim 18, wherein the space comprises a through hole defined by the heat dissipation core.
